(19) United States
(12) Patent Application Publication
(10) Pub. No.: US 2026/0148763 A1
(43) Pub. Date: May 28, 2026

(54) STACKED DYNAMIC RANDOM ACCESS MEMORY (DRAM) DEVICE WITH MULTIPLE MASTER DIE

(71) Applicant: Rambus Inc., San Jose, CA (US)

(72) Inventors: Torsten Partsch, Raleigh, NC (US); Brent Steven Haukness, Sunnyvale, CA (US); Wendy Elsasser, Austin, TX (US); Dongyun Lee, Sunnyvale, CA (US)

(21) Appl. No.: 19/121,756

(22) PCT Filed: Oct. 16, 2023
(86) PCT No.: PCT/US2023/035195

§ 371 Date: Apr. 16, 2025

Related U.S. Application Data
(60) Provisional application No. 63/417,073, filed on Oct. 18, 2022.

(51) Int. Cl. G11C 11/4093; G11C 11/4096

(52) U.S. Cl. CPC G11C 11/4093; G11C 11/4096

(57) ABSTRACT

A stacked die device includes a first master dynamic random access memory (DRAM) die having a first command interface to receive first commands and a first data interface to transfer first data. A second master DRAM die is stacked with the first master DRAM die and includes a second command interface to receive second commands that are independent of the first commands, and a second data interface to transfer second data that is independent of the first data. The first and second master DRAM die form respective portions of first and second memory channels. A third DRAM die is stacked with the first and second master DRAM die and includes a first selectively-enabled data input/output (I/O) circuit coupled to the first master DRAM die. A fourth DRAM die is stacked with the other die, and includes a second selectively-enabled data input/output (I/O) circuit coupled to the second master DRAM die.

### TECHNICAL FIELD

The disclosure herein relates to memory systems, memory devices, and associated methods.

### BRIEF DESCRIPTION OF THE DRAWINGS

Embodiments of the disclosure are illustrated by way of example, and not by way of limitation, in the figures of the accompanying drawings and in which like reference numerals refer to similar elements and in which:

FIG. 1 illustrates one embodiment of a multi-channel and multi-rank memory device that employs a stacked die architecture.

FIG. 2 illustrates data configuration logic (magnified callout 2-1) and command/address configuration logic (magnified callout 2-2) employed by each die of the stacked die architecture of FIG. 1.

FIG. 3A illustrates one embodiment of data and C/A signal flow for a first channel of the memory device shown in FIG. 1.

FIG. 3B illustrates one embodiment of data and C/A signal flow for a second channel of the memory device shown in FIG. 1.

FIG. 4 illustrates one embodiment of a multi-channel memory device similar to the embodiment of FIG. 1 and including a data interface that is wider than the embodiment of FIG. 1.

FIG. 5 illustrates the interface circuitry employed by the multi-channel memory device of FIG. 4.

FIG. 6A illustrates one embodiment of data and C/A signal flow for a first channel of the memory device shown in FIG. 4.

FIG. 6B illustrates one embodiment of data and C/A signal flow for a second channel of the memory device shown in FIG. 4.

FIG. 7 illustrates one embodiment of a multi-channel and multi-rank memory device similar to the embodiment of FIG. 1 and including a data interface that is wider than the embodiment of FIG. 1.

FIG. 8 illustrates a further embodiment of a stacked memory device that utilizes a wire-bonding technique to interconnect a die stack that is organized in an interleaved configuration.

FIG. 9 illustrates a further embodiment of a stacked memory device that utilizes a wire-bonding technique to interconnect a die stack that is organized in a non-interleaved configuration.

### DETAILED DESCRIPTION

Memory devices, modules, systems and associated methods are disclosed. In one embodiment, a dynamic random access memory (DRAM) device is disclosed. The DRAM device includes a first master DRAM die having a first command interface to receive first commands and a first data interface to transfer first data. The first master DRAM die forms at least a portion of a first memory channel and buffers signals transferred between an external integrated circuit (IC) device and other portions of the first memory channel. A second master DRAM die is stacked with the first master DRAM die and includes a second command interface to receive second commands that are independent of the first commands, and a second data interface to transfer second data that is independent of the first data. The second master DRAM die forms at least a portion of a second memory channel and buffers signals transferred between the external IC device and other portions of the second memory channel. A third DRAM die is stacked with the first master DRAM die and the second master DRAM die and includes a first selectively-enabled data input/output (I/O) circuit coupled to the first master DRAM die. A fourth DRAM die is stacked with the first master DRAM die, the second master DRAM die, and the third DRAM die, and includes a second selectively-enabled data input/output (I/O) circuit coupled to the second master DRAM die. Some embodiments described herein may configure the third and fourth DRAM die as responder die, thereby adding a second rank of memory for each channel, by disabling the first and second selectively-enabled data I/O circuits. Other embodiments may configure the third and fourth DRAM die as sub-master die, to form channels having a larger data width. In some embodiments, each die includes register storage to store configuration information that is used to configure the die. By employing multiple master die to define multiple channels in a stacked DRAM device, power dissipation and device footprint area may be reduced, thereby correspondingly reducing the cost of memory modules within, for example, a data center environment.

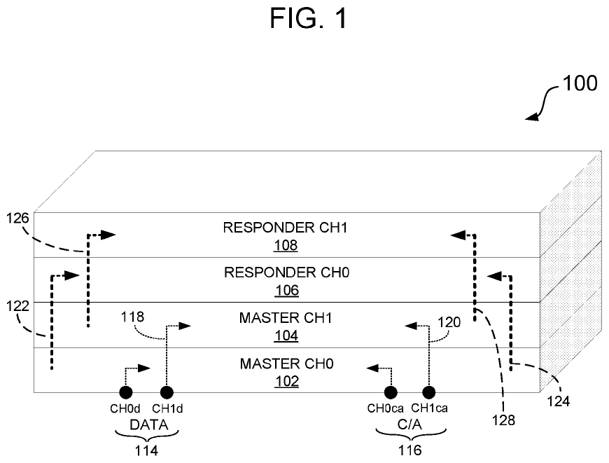

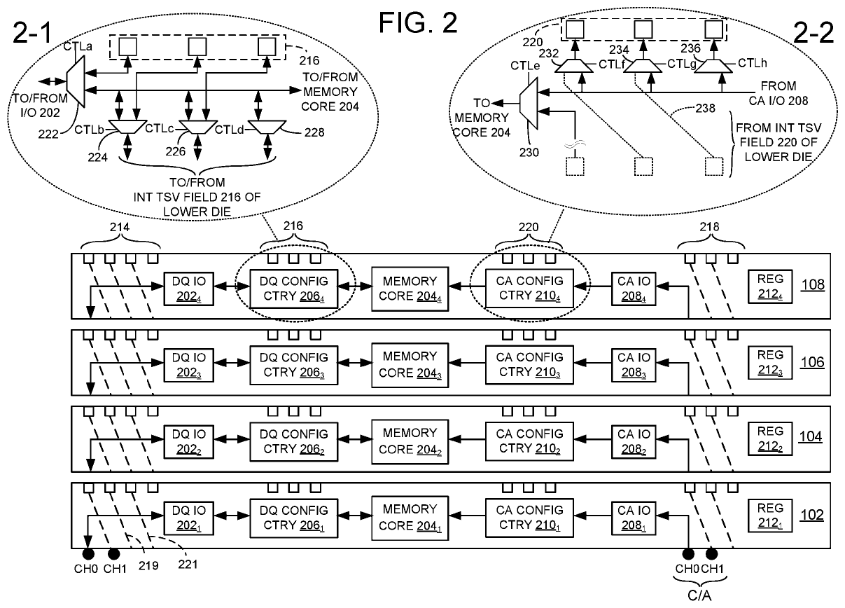

Referring now to FIG. 1, a stacked memory device, generally designated 100, is shown that includes multiple memory die 102, 104, 106 and 108 that are vertically stacked into a unitary semiconductor package. For one embodiment, the multiple memory die 102, 104, 106 and 108 take the form of dynamic random access memory (DRAM) integrated circuit (IC) die, or chips, that are substantially identical in structure, and include configuration circuitry to configure each die as a master die, a responder die, or a sub-master die, depending on the application and positioning of the die in the stack. Further detail regarding embodiments of data configuration circuitry and C/A configuration circuitry to carry out the configuring is described below and shown in FIG. 2.

Further referring to FIG. 1, for one embodiment, a bottom-most first DRAM die 102 of the stacked memory device 100 is configured as a first master memory die that forms at least a portion of a first memory channel CH0. As a master memory die, the first DRAM die 102 interfaces directly with an external memory controller (not shown), and provides a buffering functionality between the external memory controller and any other die that may be placed in the stacked memory device 100 for the first memory channel CHO. The first master memory die 102 also serves as a first rank of memory for the first memory channel CH0. Since the first DRAM die 102 acts as a buffer, the entire first memory channel CH0 is seen as a single load from the perspective of the memory controller, thereby reducing capacitance on the first memory channel and improving signaling performance. For one embodiment, the first master memory die 102 is formed with an external data interface DATA 114 including a first set of data contacts CH0d for the first memory channel CH0, and an external C/A interface C/A 116 including a first set of C/A contacts CH0ca for the first memory channel CH0. The first master memory die 102 is further formed with a second set of data contacts CH1d for a second memory channel CH1, and a second set of C/A contacts CH1ca for the second memory channel CH1. The external data and C/A interfaces DATA 114 and C/A 116 couple to the external memory controller (not shown) via respective data and C/A buses (not shown).

With continued reference to FIG. 1, for one embodiment the second DRAM die 104 of the stacked memory device 100 is stacked directly on the first DRAM die 102. The second DRAM die is configured as a second master memory die that forms a first rank of the second memory channel CH1. The second DRAM die 104 includes an internal data interface that couples to the second set of data contacts CH1d of the first DRAM die 102, and an internal C/A interface, shown in FIG. 2, that couples to the second set of C/A contacts CH1ca of the first DRAM die 102. For one embodiment, routing of the data and C/A signals between the first and second master die 102 and 104 is carried out by various sets of through-silicon-vias (TSVs), at 118 and 120, shown and described below with respect to FIG. 2.

As noted above, for one embodiment, the first and second DRAM die 102 and 104 are configured as master die that form the first ranks of respective first and second memory channels CH0 and CH1. The separate channels, CH0 and CH1, transfer data independently of one another in response to commands that are received independent from each other. This allows for finer granularity accesses that may be carried out in parallel, or carried out substantially concurrently.

Further referring to FIG. 1, the third DRAM die 106 of the stacked memory device 100 is configured as a first responder memory die that forms another portion of the first memory channel CH0 by adding storage capacity in the form of a second rank. As a responder memory die, the third DRAM die 106 interfaces indirectly with the external memory controller (not shown) via the first master DRAM die 102. Since the third DRAM die 106 communicates with the memory controller through the first master DRAM die, the data and C/A input/output (I/O) circuitry for the third DRAM die may be disabled, thus saving power. For one embodiment, routing of the data and C/A signals between the first and third DRAM die 102 and 106 is carried out by various sets of through-silicon-vias (TSVs), at 122 and 124, shown and described below with respect to FIG. 2.

With continued reference to FIG. 1, the fourth DRAM die 108 of the stacked memory device 100 is configured as a second responder memory die that forms another portion of the second memory channel CHI by adding storage capacity in the form of a second rank. Similar to the third DRAM die 106, the fourth DRAM die 108 interfaces indirectly with the external memory controller (not shown) via the second master DRAM die 104, and is also configured with its data and C/A I/O circuitry disabled. For one embodiment, routing of the data and C/A signals between the second and fourth DRAM die 104 and 108 is carried out by various sets of through-silicon-vias (TSVs), at 126 and 128, and described in further detail below with respect to FIG. 2.

Further referring to FIG. 1, specific embodiments for the DRAM memory die 102, 104, 106 and 108 may be compliant with various DRAM standards, including double data rate (DDR) variants, low power (LPDDR) versions, high bandwidth (HBM), and graphics (GDDR) types. Additional embodiments may stack the memory die together in a common package, or in separate packages stacked upon each other. Yet other embodiments may employ multiple memory devices on a substrate (not shown) in a memory module configuration for high-capacity applications. While only four die are shown in FIG. 1, the architecture described herein is scalable to support any number of channels and ranks, depending on the application.

FIG. 2 illustrates one embodiment of the stacked memory device 100 of FIG. 1 in further detail. Each of the four DRAM die 102, 104, 106 and 108 include selectively-enabled data (DQ) input/output (I/O) circuitry 202 that couples to a memory core 204 via data configuration circuitry 206. C/A I/O circuitry 208 couples to the memory core 204 through C/A configuration circuitry 210. For some embodiments, register storage 212 is included in each die to store configuration settings for the given die.

For one embodiment, and further referring to FIG. 2, each die includes an external data TSV field, at 214, and an internal data TSV field, at 216. The external data TSV field 214 is patterned such that TSV connections between adjacent die are offset or shifted by a TSV position. The pattern may take the form of a helix, a “double-S”, or any other pattern that accomplishes the desired positional shift between adjacent (immediately above or below) die. For some embodiments, when configuring which die is to be a master or responder for a certain channel, its position at a certain level in the die stack is dictated by the TSV pattern. In the case of the external data TSV field 214, and for the specific embodiment of FIG. 2, the pattern only connects directly to the sets of data contacts labeled CH0 and CH1. Other TSV paths, such as at 219 and 221 do not have a connection to the external interface, and thus create no loads on the channels. The external data TSV field 214 thus allows for stacking of substantially-identical die while presenting only a single data I/O load per channel to the memory controller (not shown). The internal data TSV field 216 is also configured to shift TSV connection positions between die, and determines a data rank selection for a given die. Each die also includes an external C/A TSV field, at 218, and an internal C/A TSV field 220. Similar to the data TSV fields 214 and 216, the external C/A TSV field 218 allows for the die stack to present a single C/A I/O load from the perspective of the memory controller. For some embodiments, the internal C/A TSV field 220 dictates a certain memory rank or secondary master die selection.

With continued reference to FIG. 2, and more specifically to magnified callout 2-1, one embodiment of the data configuration circuitry 206 includes a data I/O selector 222 that passes signals bidirectionally between the data I/O circuitry 202 and either the memory core 204 or the internal data TSV fields 216 for connecting to a different die. The I/O selector 222 may be enabled/disabled in response to a control signal CTLa. A set of internal data TSV path selectors 224, 226, and 228 correspond to the internal data TSV field 216 from a lower die and are responsive to respective control signals CTLb, CTLc and CTLd to steer data signals between a given lower TSV position and either the memory core 204 or a higher TSV position that is shifted from the lower TSV position. For one embodiment, the control signals are fed to the selectors from the register storage 212 to configure the memory device during an initialization mode of operation.

Further referring to FIG. 2, and more specifically to magnified callout 2-2, the C/A configuration circuitry 210 includes a C/A I/O selector 230 that passes C/A signals unidirectionally from the C/A I/O circuitry 208 to the memory core 204. The C/A I/O selector 230 may be enabled/disabled in response to a control signal CTLe. A set of internal data TSV path selectors 232, 234, and 236 correspond to the internal C/A TSV field 220 and are responsive to respective control signals CTLf, CTLg and CTLh to steer command and address signals from either the C/A I/O circuitry 208 or a given lower TSV position that is shifted from the higher TSV position, as shown at 238, for example.

Configuring the multi-die memory device of FIG. 2 to realize a two-channel, two-rank memory device may occur in a variety of ways. For one embodiment, the data and C/A configuration circuitry 206 and 210 of each die may be pre-configured or fixed during manufacture, prior to installation of the packaged DRAM device in a higher-level assembly. For other embodiments, the configuration circuitry 206 and 210 may be programmed or configured partially or completely in the field by a user. This may be performed via a manual setting of pins on a module or board upon which the device is mounted to generate the desired control signals or during an initialization mode of operation where the control signals may be retrieved, for example, from the register storage or received via calibration control signals from the memory controller. In some instances, on-the-fly reconfiguring of certain package topologies of the memory device 100 may be performed during the data transfer mode of operation such as through one or more MRS control signals included in the C/A signal stream. Additionally, it is assumed that the external packaging interface will generally only directly connect to a small subset of the possible TSV positions of the external data and C/A TSV fields 214 and 218. Thus, the small subset of positions may be thought of as a starting reference set of positions that are only directly connected to the first master die 102, with the subsequent die above the first master die 102 connecting to shifted TSV positions that are decoupled from the external interface direct connections.

Further referring to FIG. 2, specific configuration settings for the data configuration circuitry 206 and the C/A configuration circuitry 210 will be described for one specific embodiment to configure the DRAM device 100 into a two-channel, two-rank memory device. Since per-die configurations are being described relative to other die, identifiers for each die will be specified with a subscript denoting the die level. The data configuration circuitry 206₁ for the first master die 102 is configured such that the data I/O selector 222 is enabled, resulting in a direct signal flow between the data I/O circuitry 202₁ of the first die 102 and the memory core 204₁ of the first die 102. The data configuration circuitry 206ᵢ also provides a selection between a connection to the memory core 204₁ of the first die 102 or a first position of the internal data TSV field 216 of the first die 102. The internal data selectors 224, 226, and 228 of the first die 102 are disabled, since there is no die beneath the first master die 102, and thus no signals from an underlying internal data TSV field. The C/A configuration circuitry 210₁ for the first master die 102 is configured such that the C/A I/O selector 230 is enabled, resulting in a direct command and address signal flow from the C/A I/O circuitry 208₁ to the memory core 204₁ of the first die 102. In addition, the second one of the set of internal C/A TSV selectors 234 of the first die 102 is enabled to pass the C/A signals up to the second DRAM die 104 at a first TSV position.

The second DRAM die 104 has its data configuration circuitry settings configured similar to the first die 102 such that a first one of the set of internal data TSV path selectors, at 224, is enabled, and the remaining selectors 226 and 228 disabled. The enabled selector 224 provides a first channel CH0 data path from the first DRAM die 102 up to a second TSV position of the third DRAM die 106. As the second master die and the first rank for the second channel CH1, the selector circuitry 222 is enabled to provide a direct connection between the data I/O circuitry 202₂ of the second die to the memory core 204₂ of the second die. The selector 222 also provides a selection between a connection to the memory core 204₂ of the second die or a first position of the internal data TSV field 216 of the second die. The C/A configuration circuitry 210₂ of the second die 104 is configured such that a first one of the set of internal C/A TSV path selectors, at 232, is enabled, to pass C/A signals for the first channel to the third die 106. The second one, at 234, of the set of internal C/A TSV path selectors is also enabled to pass C/A signals for the second channel to the third die 106. The third one of the set of internal C/A TSV selectors, at 236, is disabled.

With continued reference to FIG. 2, the third DRAM die 106 is configured, as a responder die, with both the data I/O circuitry 202₃ and the C/A I/O circuitry 208₃ disabled. The first one of the internal data TSV selectors 224 is enabled and couples to the second DRAM die 104 through the first internal data TSV position to pass data for the second channel between the second die 104 and the fourth die 108. A second one of the internal data TSV selectors 226 is enabled and couples to the second DRAM die 104 through the second internal data TSV position. The internal data TSV selector 226 is further configured to connect to the memory core 204₃ of the third DRAM die 106 and not the next-level TSV field. The C/A configuration circuitry 210₃ of the third die 106 is configured with the C/A I/O selector 230 enabled to receive C/A signals from the first TSV field position as fed from the second DRAM die 104. The first internal C/A TSV selector 232 is enabled to pass C/A signals for the second channel CH1 from the second die 104 to the fourth die 108.

Further referring to FIG. 2, the fourth die 108 is configured with both the data I/O circuitry 202₄ and the C/A I/O circuitry 208₄ disabled. In supporting solely data transfers for the second rank of the second channel CH1, the data configuration circuitry 206₄ for the fourth die 108 has the second internal data TSV selector 226 enabled to pass data between the third die 106 (from the first internal data TSV selector 224) and the memory core 204₄ of the fourth die 108. The first and third internal data TSV selectors 224 and 228 may be disabled. The C/A configuration circuitry 210₄ of the fourth die is configured such that the C/A selector 230 is enabled to receive C/A signals from the internal TSV field 220 of the third die 106. The internal C/A TSV selectors 232, 234 and 236 may be disabled (since there are no further die above the fourth die in the stack.

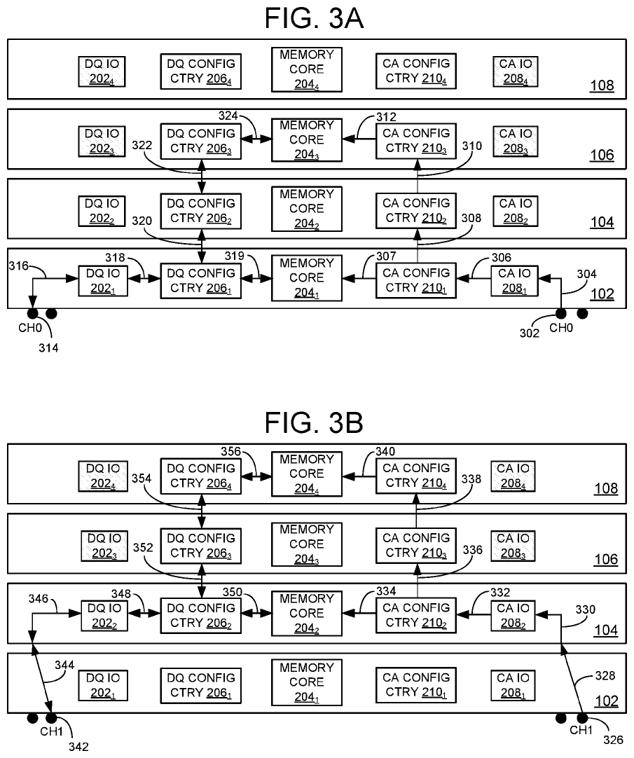

Referring now to FIG. 3A, with the first, second, third and fourth die 102, 104, 106 and 108 configured as described above, data and C/A signal flow for data transfers involving the two ranks for the first memory channel CH0 is shown. For a given transaction for the first channel CH0, various command and address signals are received at the external C/A interface contacts of the first DRAM die 102 for the first channel CH0, at 302. The C/A signals are then fed to the C/A I/O circuitry 208₁, at 304, then forwarded to the C/A configuration circuitry 210₁ of the first DRAM die 102, at 306. The C/A signals are conditionally fed from the C/A configuration circuitry 210₁ of the first die 102 to either one or both of the memory core 204₁, at 307, and the C/A configuration circuitry 210₂ of the second die 104 via the internal C/A TSV pattern, at 308. The C/A configuration circuitry 210₂ of the second die 104 then passes the C/A signals to the C/A configuration circuitry 210₃ of the third die 106, at 310, via the internal C/A TSV pattern. At 312, the C/A signals are fed to the memory core 204₃ of the third memory die 106 by the C/A configuration circuitry 210₃ of the third die 106. For one embodiment, based on a value of a chip select control signal in the C/A signal stream, either the memory core 204₁ of the first die 102 or the memory core 204₃ of the third die 106 is accessed for the first channel CH0 transfer operation.

Further referring to FIG. 3A, data involved in the transaction specified by the C/A signals traverses the die in a signal flow direction based on whether the transaction involves a write operation or read operation. For a write operation, write data is received by the external data interface, at 314, and passed to the data I/O circuitry 202₁ of the first memory die 102, at 316. The data I/O circuitry 202₁ then drives the write data, at 318, to the data configuration circuitry 206₁ of the first die 102. The data configuration circuitry 206₁ of the first die 102 then conditionally forwards the write data to the memory core 204₁, at 319, or to the data configuration circuitry 206₂ of the second die 104, at 320, and based on the value of the chip select control signal in the C/A signal stream or other similar control signal. If the data is forwarded to 206₂ a further vertical transfer occurs, at 322, between the data configuration circuitry 206₂ of the second die 104 and the data configuration circuitry 206₃ of the third die 106. The data configuration circuitry 206₃ of the third die 106 then feeds the write data to the memory core 204₃, at 324. The memory core selected by the chip select signal, either memory core 204₁ or 204₃, receives the write data, and performs the write operation in the accessed memory core. Read operations are similar, but follow a reverse signal path with respect to write operations.

FIG. 3B illustrates signal flow during a data transfer mode of operation for the stacked memory device 100 of FIG. 1 for the second memory channel CH1. While only the second and fourth DRAM die 104 and 108 are used for the second memory channel CH1, the first and third DRAM die 102 and 106 are still involved with internal TSV signal routing between the second and fourth DRAM die 104 and 108. The first and third DRAM die 102 and 106 are configured accordingly to perform the signal routing support. It should also be understood that all of the configuration settings described above with respect to the first memory channel CH0 remain configured for each die in addition to the settings for configuring each die to support the second memory channel CH1.

Further referring to FIG. 3B, the external data and C/A TSV fields 214 and 218 (FIG. 2) connect to the external interface contacts assigned to the second memory channel CH1, such as at 342 and 326, and shift the respective data and C/A paths by a TSV position for the second DRAM die 104. The data configuration circuitry 206₁ and the C/A configuration circuitry 210₁ for the first DRAM die 102 are not configured for supporting the second channel CH1, and warrant no further description.

With continued reference to FIG. 3B, the data configuration circuitry 206₂, 206₃ and 206₄ for the second, third, and fourth DRAM die 104, 106, and 108, and are generally configured in a similar way for the second memory channel CH1 as the first, second and third DRAM die 102, 104, and 106 for the first memory channel CH0, except with the enabled internal data TSV selectors offset by a TSV position. A similar configuration scheme is exhibited for the C/A configuration circuitry 210₂, 210₃, and 210₄ for the second, third, and fourth DRAM die 104, 106, and 108.

Further referring to FIG. 3B, and with the stack of DRAM die configured as described above, data and C/A signal flow for data transfers involving the two ranks for the second memory channel CH1 is shown. For a given transaction for the second channel CH1, command and address signals are received at the external C/A interface contacts of the first DRAM die 102 for the second channel CH1, at 326. The C/A signals bypass the C/A I/O circuitry 208₁ (which may be disabled to save power) of the first memory die 102 via the external C/A TSV pattern of the first die, at 328, and are then fed to the C/A I/O circuitry 208₂, at 330, via the external C/A TSV pattern of the second die 104. The C/A signals are then forwarded to the C/A configuration logic 210₂ of the second DRAM die 104, at 332. The C/A signals are conditionally fed from the C/A configuration circuitry 210₂ of the second die 104 to either one of or both of the memory core 204₂, at 334, and the C/A configuration circuitry 210₃ of the third die 106 via the internal C/A TSV pattern, at 336, and based on the value of the chip select control signal in the C/A signal stream or other similar control signal. In the second case, the C/A configuration circuitry 210₃ of the third die 106 then passes the C/A signals to the C/A configuration circuitry 210₄ of the fourth die 108, at 338, via the internal C/A TSV pattern. At 340, the C/A signals are fed to the memory core 204₄ of the fourth memory die 108 by the C/A configuration circuitry 210₄ of the fourth die 108. Based on the value of the chip select control signal in the C/A signal stream or other similar control signal, either the memory core 204₂ of the second die 104 or the memory core 204₄ of the fourth die 108 is accessed for the transfer operation.

Further referring to FIG. 3B, for a write operation, write data is received by the external data interface, at 342, and bypasses the data I/O circuitry 202₁ of the first memory die 102, at 344, due to the routing of the external TSV pattern. The data is then fed to the data I/O circuitry 202₂ of the second memory die 104, at 346. The data I/O circuitry 202₂ then drives the write data, at 348, to the data configuration circuitry 206₂ of the second die 104. The data configuration circuitry 206₂ of the second die 104 then forwards the write data to the memory core 204₂, at 350, and to the data configuration circuitry 206₃ of the third memory die 106, at 352. A further vertical transfer occurs, at 354, between the data configuration circuitry 206₃ of the third memory die 106 and the data configuration circuitry 206₄ of the fourth memory die 108. The data configuration circuitry 206₄ of the fourth die 108 then feeds the write data to the memory core 204₄, at 356. The memory core activated by the chip select signal, either memory core 204₂ or 204₄, receives the write data, and performs the write operation in the accessed memory core. Read operations are similar, but follow a reverse signal path with respect to the write operations.

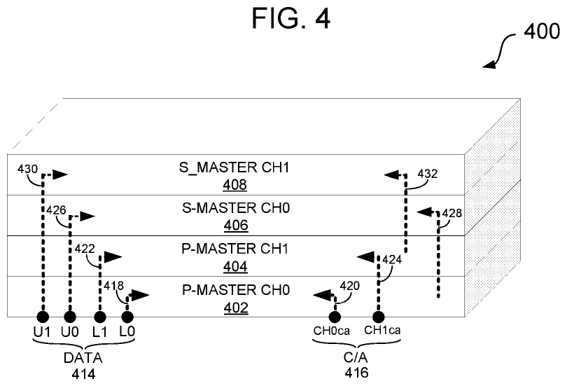

FIG. 4 illustrates a further embodiment of a stacked memory device, generally designated 400. While the stacked memory device 100 of FIG. 1 is configured as a two-channel, two-rank device, the stacked memory device of FIG. 4 is configured as a two-channel single-rank device that exhibits a data width, for one embodiment, that is twice the data width of the prior-described stacked memory device 100. For one embodiment, the stacked memory device 400 includes multiple configurable memory die 402, 404, 406 and 408 that are vertically stacked and take the form of dynamic random access memory (DRAM) integrated circuit (IC) die, or chips, that are individually substantially identical in structure to the die 102, 104, 106 and 108 of FIGS. 1-3.

Further referring to FIG. 4, for one embodiment, the bottom-most first DRAM die 402 of the stacked memory device 400 is configured as a first primary master memory die that forms at least a portion of a first data width of a first memory channel CH0. The first primary DRAM die 402 interfaces directly with an external memory controller (not shown), and serves as a portion of a first rank of memory for the first memory channel CH0. For one embodiment, the first master memory die 402 is formed with an external data interface DATA 414 including first and second sets of data contacts “LO” and “UO” for the first memory channel CH0, and third and fourth sets of data contacts “L1” and “U1” for the second memory channel CH1. An internal data interface, at 418, of the first primary master die 402 directly couples the memory core of the first primary master memory die 402 to the first set of contacts L0. The first primary master die 402 also includes an external C/A interface C/A 416 including a first set of C/A contacts CH0ca for the first memory channel CH0 and a second set of C/A contacts CH1ca for the second memory channel CH1. An internal C/A interface, at 420, of the first primary master die 402 directly couples the memory core of the first primary master memory die 402 to the first set of C/A contacts CH0ca. The external data and C/A interfaces DATA 414 and C/A 416 couple to the external memory controller (not shown) via respective data and C/A buses (not shown).

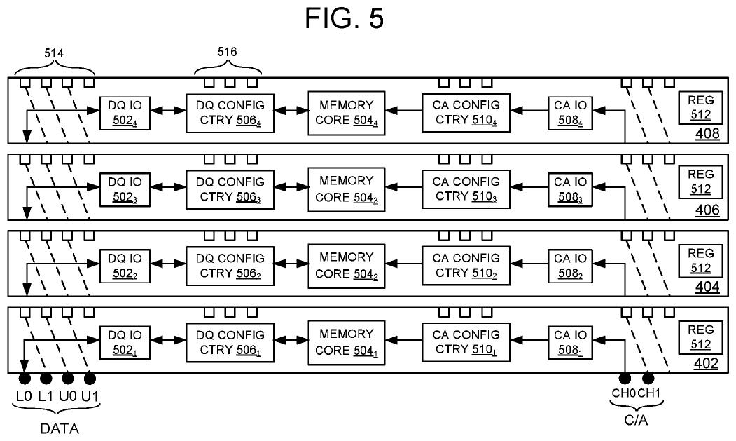

With continued reference to FIG. 4, for one embodiment, the second DRAM die 404 of the stacked memory device 400 is stacked directly on the first DRAM die 402. The second DRAM die 404 is configured as a second primary master memory die that forms a portion of the first rank of the second memory channel CH1. The second DRAM die 404 includes an internal data interface, at 422, that couples the memory core to the second set of data contacts L1 of the first DRAM die 402, and an internal C/A interface, at 424, that couples the memory core to the second set of C/A contacts CH1ca of the first primary DRAM die 402. For one embodiment, routing of the data and C/A signals between the first and second primary master die 402 and 404 is carried out by various sets of through-silicon-vias (TSVs), shown and described below with respect to FIG. 5.

As noted above, for one embodiment, the first and second primary master DRAM die 402 and 404 are configured as primary master die that form portions of the first ranks of respective first and second memory channels CH0 and CH1. The separate channels, CH0 and CH1, transfer data independently of one another in response to commands that are received independent from each other. This allows for finer granularity accesses to that may be carried out in parallel, or substantially concurrently.

Further referring to FIG. 4, the third DRAM die 406 of the stacked memory device 400 is configured as a first secondary master memory die that expands the data width of the first memory channel CH0 by adding separate storage capacity and interface resources that are responsive to a given set of C/A signals in parallel with the first primary master die 402. As a secondary master memory die, the third DRAM die 406 interfaces with the external memory controller (not shown) via the set of external interface contacts “U0.” An internal set of data TSVs, at 426, couples the contacts UO to the memory core of the third die 406. An internal set of C/A TSVs, at 428, couples the contacts CH0ca, via the first die 402, to the memory core of the third die 406. Since the third DRAM die 406 communicates data with the memory controller, the data input/output (I/O) circuitry for the third DRAM die remains enabled.

With continued reference to FIG. 4, the fourth DRAM die 408 of the stacked memory device 400 is configured as a second secondary master memory die that expands the data width of the second memory channel CHI by adding separate storage capacity and interface resources that are responsive to a given set of C/A signals in parallel with the second primary master die 404. Similar to the third DRAM die 406, the fourth DRAM die 408 interfaces with the external memory controller (not shown) via the set of external interface contacts “U1.” An internal set of data TSVs, at 430, couples the contacts U1 to the memory core of the fourth die 406. An internal set of C/A TSVs, at 432, couples the contacts CH1ca, via the second die 404, to the memory core of the fourth die 408. Since the fourth DRAM die 408 communicates with the memory controller, the data_input/output (I/O) circuitry for the fourth DRAM die 408 remains enabled.

While only four die are shown in FIG. 4 to support a two-channel device, it should be understood that the general architecture is scalable to support a higher number of channels and widths by including additional die and modifying the external TSV patterns accordingly.

FIG. 5 illustrates one embodiment of the stacked memory device 400 of FIG. 4 in further detail. Each of the four DRAM die 402, 404, 406 and 408 include selectively-enabled data (DQ) I/O circuitry 502 that couples to a memory core 504 via data configuration circuitry 506. C/A I/O circuitry 508 couples to the memory core 504 through C/A configuration circuitry 510. For some embodiments, register storage 512 is included in each die to store configuration settings for the given die. At this point, each of the die 402, 404, 406 and 408 are of a similar construction as the die 102, 104, 106 and 108 of FIG. 2.

For one embodiment, and further referring to FIG. 5, each die includes an external data TSV field of TSVs, at 514, and an internal data TSV field, at 516. While the internal data TSV field is similar to that described for the die embodiments of FIG. 2, the external data TSV field 514 is scaled in size to support an extended data width with respect to the earlier-described embodiments. Thus, to support a data width that is twice the data width of the stacked memory device 100 (FIG. 1), one embodiment of the external data TSV field 514 for the stacked memory device 400 employs twice as many sets of TSVs and interface contacts as employed by the stacked memory device 100.

Further referring to FIG. 5, specific configuration settings for the data configuration circuitry and the C/A configuration circuitry 510 will be described for one specific embodiment to configure the memory device 400 into a two-channel, double-width memory device. The data configuration circuitry 5061 for the first master die 402 is configured such that the data I/O selector 222 (FIG. 2-1) is enabled, resulting in a direct signal flow between the data I/O circuitry 502₁ of the first die 402 and the memory core 504₁ of the first die 402. The internal data selectors 224, 226, and 228 (FIG. 2) are disabled, since there is no die beneath the first primary master die 402, and thus no signals from an underlying internal data TSV field. The C/A configuration circuitry 510₁ for the first primary master die 402 is configured in the same manner as the C/A configuration circuitry for the stacked memory device 100 of FIG. 2.

The second DRAM die 404 is configured similar to the first die 402, as a primary master die, but receives its external interface signals from the contacts L1 of the first die 402 and through the external TSV pattern. The data configuration circuitry 506₂ for the second master die 404 is configured such that the data I/O selector 222 (FIG. 2-1) is enabled, resulting in a direct signal flow between the data I/O circuitry 502₂ of the second die 404 and the memory core 504₂ of the second die 404. The C/A configuration circuitry 510₂ of the second die 404 is configured in the same manner as the C/A configuration circuitry for the stacked memory device 100 of FIG. 2.

With continued reference to FIG. 5, the third DRAM die 406 is configured with the data I/O circuitry 502₃ enabled and the C/A I/O circuitry 508₃ disabled. The data configuration circuitry 506₃ is configured to provide a direct connection to the memory core 504₃. The C/A configuration circuitry 510 of the third die 406 is configured in a similar manner as the C/A configuration circuitry for the stacked memory device 100 of FIG. 2. The fourth DRAM die 408 is not involved in any data or C/A signal routing for the first memory channel CH0.

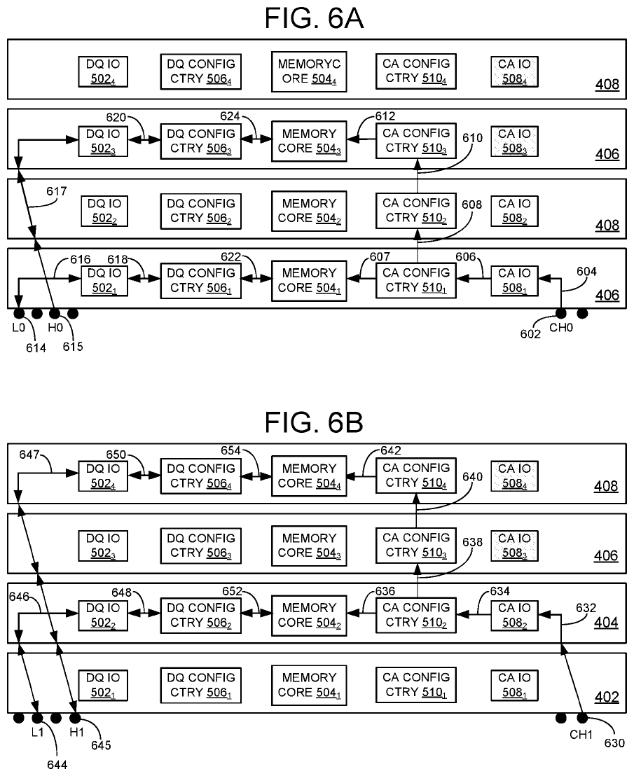

Referring now to FIG. 6A, with the first, second, third and fourth die 402, 404, 406 and 408 configured as described above, data and C/A signal flow for data transfers involving the first memory channel CH0 is shown. For a given transaction for the first channel CH0, various command and address signals are received at the external C/A interface contacts of the first DRAM die 402 for the first channel CH0, at 602. The C/A signals are then fed to the C/A I/O circuitry 508₁, at 604, then forwarded to the C/A configuration logic 510₁ of the first DRAM die 402, at 606. The C/A signals are fed from the C/A configuration circuitry 510₁ of the first die 402 to both the memory core 504₁, at 607, and to the C/A configuration circuitry 510₂ of the second die 404 via the internal C/A TSV pattern, at 608. The C/A configuration circuitry 510₂ of the second die 404 then passes the C/A signals to the C/A configuration circuitry 510₃ of the third die 406, at 610, via the internal C/A TSV pattern. At 612, the C/A signals are fed to the memory core 504₃ of the third memory die 406 by the C/A configuration circuitry 510₃ of the third die 406. For one embodiment, a common chip select control signal (or other control signal) in the C/A signal stream accesses both the memory core 504₁ of the first die 402 and the memory core 504₃ of the third die 406 for the transfer operation.

Further referring to FIG. 6A, data involved in the transaction specified by the C/A signals traverses the die in a signal direction based on whether the transaction involves a write operation or read operation. For a write operation, first and second portions of the write data are received by the separate sets of contacts LO and HO of the external data interface, at 614 and 615, and passed to the data I/O circuitry 5021 of the first memory die 402, at 616, and passed to the data I/O circuitry 502₃ of the third memory die 406, at 617, which traverses the external data TSV patterns of the first and second die 402 and 404. The data I/O circuitry 502₁ of the first die 402 then drives the first portion of the write data, at 618, to the data configuration circuitry 506₁ of the first die 402. In parallel with the data I/O circuitry 502₁ of the first die 402, the data I/O circuitry 502₃ of the third die 406 drives the second portion of the write data to the data configuration circuitry 506₃ of the third die 406, at 620. The data configuration circuitry 506₁ of the first die 402 then forwards the first portion of the write data to the memory core 504₁, at 622, while the data configuration circuitry 506₃ of the third die 406 forwards the second portion of the write data to the memory core 504₃, at 624. Since both memory cores 504₁ and 504₃ are activated by the common chip select signal, and multiple data paths are configured from the external interface to each memory core, each memory core receives a respective portion of the write data during respective time intervals that at least partially overlap, often referred to as occurring concurrently, and performs the write operation. Read operations are similar, but follow a reverse signal path with respect to write operations.

FIG. 6B illustrates signal flow during a data transfer mode of operation for the stacked memory device 400 of FIG. 4 for the second memory channel CH1. While only the second and fourth DRAM die 404 and 408 are used for the second memory channel CH1, the first and third DRAM die 102 and 406 are still involved with internal TSV signal routing between the second and fourth DRAM die 404 and 408. The first and third DRAM die 402 and 406 are configured accordingly to perform the signal routing support. It should also be understood that all of the configuration settings described above with respect to the first memory channel CH0 remain configured for each die in addition to the settings for configuring each die to support the second memory channel CH1.

Further referring to FIG. 6B, the external data and C/A TSV fields 214 and 218 (FIG. 2) connect to the external interface contacts assigned to the second memory channel CH1, such as at 644 and 645, and shift the respective data and C/A paths by a TSV position for the second DRAM die 404. The data configuration circuitry 506₁ and the C/A configuration circuitry 510₁ for the first DRAM die 402 are not configured for supporting the second channel CH1, and warrant no further description.

With continued reference to FIG. 6B, the data configuration circuitry 506₂, 506₃ and 506₄ for the second, third, and fourth DRAM die 404, 406, and 408 are generally configured in a similar way for the second memory channel CH1 as the first, second and third DRAM die 402, 404, and 406 for the first memory channel CH0, except with the enabled internal data TSV selectors offset by a TSV position. A similar configuration scheme is exhibited for the C/A configuration circuitry 510₂, 510₃, and 510₄ for the second, third, and fourth DRAM die 404, 406, and 408.

Further referring to FIG. 6B, and with the stack of DRAM die configured as described above, data and C/A signal flow for data transfers involving the second memory channel CH1 is shown. For a given transaction for the second channel CH1, various command and address signals are received at the external C/A interface contacts of the first DRAM die 402 for the second channel CH1, at 630. The C/A signals are then fed to the C/A I/O circuitry 508₂, at 632, then forwarded to the C/A configuration logic 510₂ of the second DRAM die 404, at 634. The C/A signals are fed from the C/A configuration circuitry 510₂ of the second die 404 to both the memory core 504₂, at 636, and to the C/A configuration circuitry 510₃ of the third die 406 via the internal C/A TSV pattern, at 638. The C/A configuration circuitry 510₃ of the third die 406 then passes the C/A signals to the C/A configuration circuitry 510₄ of the fourth die 408, at 640, via the internal C/A TSV pattern. At 642, the C/A signals are fed to the memory core 504₄ of the fourth memory die 408 by the C/A configuration circuitry 510₄ of the fourth die 408. For one embodiment, a common chip select control signal (or multiple (encoded) chip select signals) in the C/A signal stream accesses both the memory core 504₂ of the second die 404 and the memory core 504₄ of the fourth die 408 for the transfer operation to be performed during a common time interval.

With continued reference to FIG. 6B, for a write operation, first and second portions of the write data are received by the separate sets of contacts L1 and H1 of the external data interface, at 644 and 645, and passed to the data I/O circuitry 502₂ of the second memory die 404, at 646, and passed to the data I/O circuitry 502₄ of the fourth memory die 408, at 647, which traverses the external data TSV patterns of the second and third die 404 and 406. The data I/O circuitry 502₂ of the second die 404 then drives the first portion of the write data, at 648, to the data configuration circuitry 506₂ of the second die 404. In parallel with the data I/O circuitry 502₂ of the second die 404, the data I/O circuitry 502₄ of the fourth die 408 drives the second portion of the write data to the data configuration circuitry 506₄ of the fourth die 408, at 650. The data configuration circuitry 506₂ of the second die 404 then forwards the first portion of the write data to the memory core 504₂, at 652, while the data configuration circuitry 506₄ of the fourth die 408 forwards the second portion of the write data to the memory core 504₄, at 654. Since both memory cores 504₂ and 504₄ are activated by the common chip select signal, and multiple data paths are configured from the external interface to each memory core, each memory core receives a respective portion of the write data during respective time intervals that at least partially overlap in time, often referred to as occurring concurrently, and performs the write operation. Read operations are similar, but follow a reverse signal path with respect to write operations.

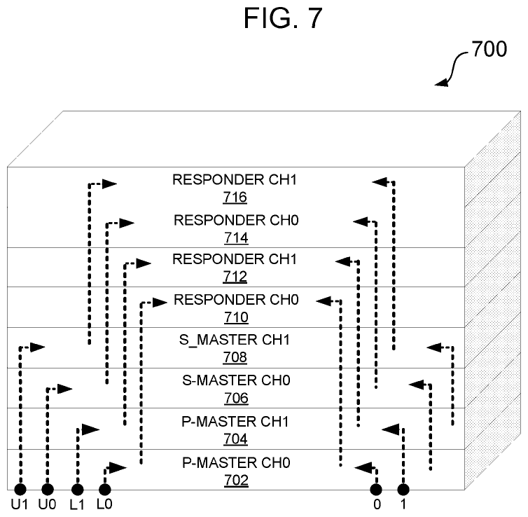

FIG. 7 illustrates a two-channel, two rank, extended width stacked die memory device, generally designated 700, that employs features from both of the embodiments shown in FIGS. 1 and 4, and described above. The stacked die memory device 700 includes eight memory die, 702, 704, 706, 708, 710, 712, 714 and 716 that are vertically stacked. Generally speaking, the bottom-most die 702, 704, 706 and 708 are configured similarly to the extended-width embodiment of FIG. 4, and are thus configured as two primary master die 702 and 704 to form respective portions of a first channel CH0 and a second channel CH1, and two secondary master die 706 and 708. To provide additional capacity, four responder die 710, 712, 714 and 716 are added, thus forming two ranks for each of the two channels. In forming the multi-rank stacked die device 700, the upper-most die 710, 712, 714, and 716 are configured similarly to the embodiment of FIG. 1, with internal TSV patterns being scaled accordingly to support the additional die levels. As with the embodiments of FIGS. 1 and 4, the embodiment of FIG. 7 may be further scaled to support any number of channels, widths and/or ranks, depending on the application.

The embodiments described above with respect to FIGS. 1-7 involve stacked die devices that employ multiple channels, multiple ranks, and extended widths that are configurable and scalable while preserving a minimal horizontal footprint. Other configurable features that some embodiments provide relate to enabling and/or disabling serialization and deserialization circuitry, depending on whether a given die is configured as a master die, a sub-master die, or a responder die. Having this ability may provide power savings in certain circumstances. For flexibility, the embodiments described above utilize through-silicon via (TSV) technology, which may be straightforwardly scaled to support varying die stack heights with improved signal integrity. In some instances, where cost considerations may warrant a reduction in flexibility and signal integrity, wire bonding stacked die may provide an acceptable alternative to TSV-based embodiments.

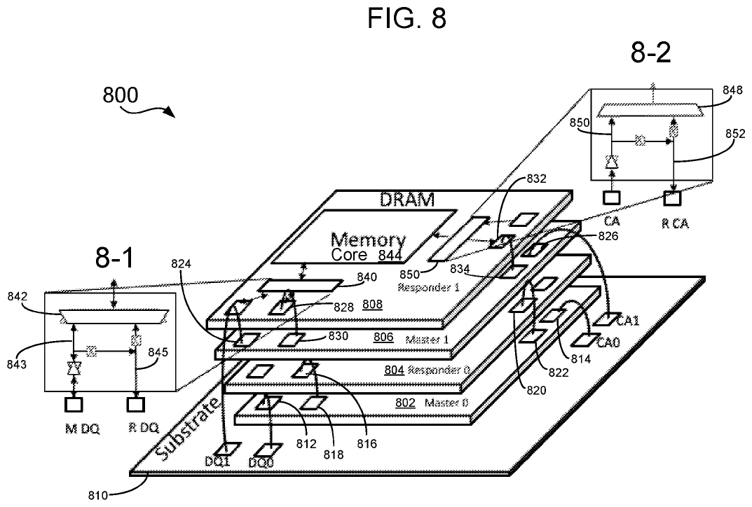

FIG. 8 illustrates one embodiment of a stacked die device 800 that interconnects multiple die 802, 804, 806 and 808 in an interleaved fashion to achieve a two-channel two-rank stacked die device using a wire-bond connection scheme. The base die 802 is mounted on a substrate 810 and is configured as a master die and first rank for a first channel and includes an external data interface pad, at 812, that connects to a data pad DQ0 formed on the substrate 810 via a wire-bond connection. The base die 802 also includes an external C/A interface pad, at 814, that is wire-bonded to a first C/A pad CAO formed on the substrate 810. Disposed directly above the base die 802 is a second die 804 that is configured as a responder die, thus forming a second rank for the first channel. The second die 804 includes an internal data interface pad, at 816, that connects to a second data interface pad of the first die 802 via a wire-bond connection, at 818. The second die 804 also includes an internal C/A interface pad, at 820, that is wire-bonded to a second C/A pad formed on the first die 802, at 822.

Further referring to FIG. 8, the third die 806 is mounted above the second die 804, and is configured as a second master die and first rank for a second channel. The third die 806 includes an external data interface pad, at 824, that connects to a data pad DQ1 formed on the substrate 810. The third die 806 also includes an external C/A interface pad, at 826, that connects to a second C/A pad CA 1 formed on the substrate 810. Disposed directly above the third die 806 is a fourth die 808 that is configured as a responder die, thus forming a second rank for the second channel. The fourth die 808 includes an internal data interface pad, at 828, that is wire-bonded to a second data interface pad of the third die 806, at 830. The fourth die 808 also includes an internal C/A interface pad, at 832, that is wire-bonded to a second C/A pad formed on the third die 806, at 834.

With continued reference to FIG. 8, each die includes data interface configuration circuitry 840 and C/A interface configuration circuitry 850. Magnified call-out 8-1 shows one embodiment of the data interface configuration circuitry 840 which includes a selector 842 for selecting one of two I/O pad paths 843 or 845 for interfacing with a memory core 844. The selection is based on whichever I/O pad is connected to another die, or the substrate 810. Magnified call-out 8-2 shows one embodiment of the C/A interface configuration circuitry 850 which includes a selector 848 for selecting between one of two I/O pad paths 850 or 852 for interfacing with the memory core 844. The selection is based on whichever C/A I/O pad is connected to another die, or the substrate 810.

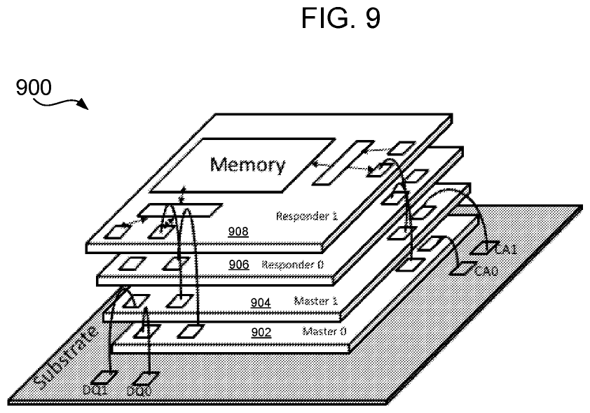

FIG. 9 illustrates one embodiment of a stacked die device 900 similar to that described above with respect to FIG. 8, including multiple die 902, 904, 906, and 908 that are interconnected in a non-interleaved fashion to achieve a two-channel two-rank stacked die device using a wire-bond connection scheme. Much of the structure for the stacked die device 900 corresponds to the structure 800 of FIG. 8, although the bottom-most die 902 and 904 are configured as master die, while the upper-most die 906 and 908 are configured as responder die.

The embodiments described above and shown FIGS. 1-9 should be understood as conceptual in nature, and should not be construed as illustrating and/or describing exact placement or layout of paths and/or connections.

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

While the embodiments are described as stacks of DRAM devices, the embodiments may also incorporate other memory types, like, for example: NAND FLASH, MRAM, RRAM, SRAM, etc.

In the foregoing description and in the accompanying drawings, specific terminology and drawing symbols have been set forth to provide a thorough understanding of the present invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘s̅i̅g̅n̅a̅l̅ n̅a̅m̅e̅’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction (e.g., via a mode register set command “MRS”) and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

In the claims:

1. A stacked die device, comprising:
a first master dynamic random access memory (DRAM) die having a first command interface to receive first commands and a first data interface to transfer first data, the first master DRAM die to form at least a portion of a first memory channel and to buffer signals transferred between an external integrated circuit (IC) device and other portions of the first memory channel;
a second master DRAM die stacked with the first master DRAM die and having a second command interface to receive second commands that are independent of the first commands, and a second data interface to transfer second data that is independent of the first data, the second master DRAM die to form at least a portion of a second memory channel and to buffer signals transferred between the external IC device and other portions of the second memory channel;
a third DRAM die stacked with the first master DRAM die and the second master DRAM die, the third DRAM die including a first selectively-enabled data input/output (I/O) circuit coupled to the first master DRAM die; and
a fourth DRAM die stacked with the first master DRAM die, the second master DRAM die, and the third DRAM die, the fourth DRAM die including a second selectively-enabled data input/output (I/O) circuit coupled to the second master DRAM die.

2. The stacked die device of claim 1, wherein for a first mode of operation:
the third DRAM die is configured with the first selectively-enabled I/O circuit disabled to define a first responder die, and the fourth DRAM die is configured with the second selectively-enabled I/O circuit disabled to define a second responder die;
wherein the first master DRAM die and the first responder die cooperate to form respective first and second ranks of the first memory channel, the first memory channel exhibiting a first data width; and
wherein the second master DRAM die and the second responder die cooperate to form respective first and second ranks of the second memory channel, the second memory channel exhibiting the first data width.

3. The stacked die device of claim 2, wherein for a second mode of operation:
the third DRAM die is configured with the first selectively-enabled I/O circuit enabled to define a first submaster die, and the fourth DRAM die is configured with the second selectively-enabled I/O circuit enabled to define a second submaster die;
wherein the first master DRAM die and the first submaster die cooperate to form the first memory channel with a second data width that is greater than the first data width; and
wherein the second master DRAM die and the second submaster die cooperate to form the second memory channel with the second data width.

4. The stacked die device of claim 3, wherein each of the first master DRAM die, the second master DRAM die, the third DRAM die and the fourth DRAM die further comprise:
register storage to store configuration information specifying a master die configuration, a responder die configuration or a submaster die configuration.

5. The stacked die device of claim 1, wherein:
each of the first master DRAM die, the second master DRAM die, the third DRAM die and the fourth DRAM die are interconnected by through-silicon-vias (TSVs).

6. The stacked die device of claim 5, wherein the TSVs for each of the first master DRAM die, the second master DRAM die, the third DRAM die and the fourth DRAM die comprise:
an external data TSV field directly coupled to an external interface of the DRAM device;
an internal data TSV field directly coupled to memory core circuitry for each of the first master DRAM die, the second master DRAM die, the third DRAM die and the fourth DRAM die; and
wherein a given data I/O circuit of the first master DRAM die, the second master DRAM die, the third DRAM die or the fourth DRAM die is disposed between the external data TSV field and the internal data TSV field.

7. The stacked die device of claim 5, wherein the TSVs for each of the first master DRAM die, the second master DRAM die, the third DRAM die and the fourth DRAM die further comprise:
an external command-address (CA) field directly coupled to an external interface of the DRAM device;
an internal CA TSV field directly coupled to memory core circuitry for each of the first master DRAM die, the second master DRAM die, the third DRAM die and the fourth DRAM die; and
wherein a given CA I/O circuit of the first master DRAM die, the second master DRAM die, the third DRAM die or the fourth DRAM die is disposed between the external CA TSV field and the internal CA TSV field.

8. The stacked die device of claim 1, wherein:
the first master DRAM die and the third DRAM die are interconnected by a first set of wire-bonds; and
the second master DRAM die and the fourth DRAM die are interconnected by a second set of wire-bonds.

9. A stacked die device, comprising:
a package substrate;
multiple stacked dynamic random access memory (DRAM) die disposed on the package substrate, the multiple stacked DRAM die including
at least two master DRAM die that form respective first ranks of a first memory channel and a second memory channel, each of the at least two master DRAM die to buffer signals transferred between an external integrated circuit (IC) device and other portions of the first memory channel and the second memory channel;
a third DRAM die including a first selectively-enabled data input/output (I/O) circuit coupled to a first one of the at least two master DRAM die; and
a fourth DRAM die including a second selectively-enabled data input/output (I/O) circuit coupled to a second one of the at least two master DRAM die.

10. The stacked die device of claim 9, wherein:
the third DRAM die is configured with the first selectively-enabled I/O circuit disabled to define a first responder die that forms a second rank for the first memory channel, the first memory channel exhibiting a first data width, and the fourth DRAM die is configured with the second selectively-enabled I/O circuit disabled to define a second responder die that forms a second rank for the second memory channel, the second memory channel exhibiting the first data width.

11. The stacked die device of claim 9, wherein:
the third DRAM die is configured with the first selectively-enabled I/O circuit enabled to define a first submaster die, the first memory channel exhibiting a second data width that is twice the first data width, and the fourth DRAM die is configured with the second selectively-enabled I/O circuit enabled to define a second submaster die, the second memory channel exhibiting the second data width.

12. The stacked die device of claim 9, wherein each of the at least two master DRAM die, the third DRAM die and the fourth DRAM die further comprise:
register storage to store configuration information specifying a master die configuration, a responder die configuration or a submaster die configuration.

13. The stacked die device of claim 9, wherein:
each of the at least two master DRAM die, the third DRAM die and the fourth DRAM die are interconnected by through-silicon-vias (TSVs).

14. The stacked die device of claim 13, wherein the TSVs for each of the at least two master DRAM die, the third DRAM die and the fourth DRAM die comprise:
an external data TSV field directly coupled to an external interface of the DRAM device;
an internal data TSV field directly coupled to memory core circuitry for each of the at least two master DRAM die, the third DRAM die and the fourth DRAM die; and
wherein a given data I/O circuit of the at least two master DRAM die, the third DRAM die or the fourth DRAM die is disposed between the external data TSV field and the internal data TSV field.

15. The stacked die device of claim 13, wherein the TSVs for each of the at least two master DRAM die, the third DRAM die and the fourth DRAM die further comprise:
an external command-address (CA) field directly coupled to an external interface of the DRAM device;
an internal CA TSV field directly coupled to memory core circuitry for each of the at least two master DRAM die, the third DRAM die and the fourth DRAM die; and
wherein a given CA I/O circuit of the first master DRAM die, the second master DRAM die, the third DRAM die or the fourth DRAM die is disposed between the external CA TSV field and the internal CA TSV field.

16. The stacked die device of claim 9, wherein:
a first one of the at least two master DRAM die and the third DRAM die are interconnected by a first set of wire-bonds; and
a second one of the at least two master DRAM die and the fourth DRAM die are interconnected by a second set of wire-bonds.

17. A stacked die device, comprising:
multiple dynamic random access memory (DRAM) die disposed in a stack;
configuration circuitry to configure the multiple DRAM die as
at least two master DRAM die that form respective first ranks of a first memory channel and a second memory channel, each of the at least two master DRAM die to buffer signals transferred between an external integrated circuit (IC) device and other portions of the first memory channel and the second memory channel;
a third DRAM die including a first selectively-enabled data input/output (I/O) circuit coupled to a first one of the at least two master DRAM die; and
a fourth DRAM die including a second selectively-enabled data input/output (I/O) circuit coupled to a second one of the at least two master DRAM die.

18. The stacked die device of claim 17, wherein:
the third DRAM die is configured by the configuration circuitry with the first selectively-enabled I/O circuit disabled to define a first responder die that forms a second rank for the first memory channel, the first memory channel exhibiting a first data width, and the fourth DRAM die is configured by the configuration circuitry with the second selectively-enabled I/O circuit disabled to define a second responder die that forms a second rank for the second memory channel, the second memory channel exhibiting the first data width.

19. The stacked die device of claim 17, wherein:
the third DRAM die is configured by the configuration circuitry with the first selectively-enabled I/O circuit enabled to define a first submaster die, the first memory channel exhibiting a second data width that is twice the first data width, and the fourth DRAM die is configured by the configuration circuitry with the second selectively-enabled I/O circuit enabled to define a second submaster die, the second memory channel exhibiting the second data width.

20. The stacked die device of claim 17, wherein the configuration circuitry further comprises:
register storage to store configuration information specifying a master die configuration, a responder die configuration or a submaster die configuration.
